(19) United States
(12) Patent Application Publication
(10) Pub. No.: US 2026/0165076 A1
(43) Pub. Date: Jun. 11, 2026

(54) SUBSTRATE PROCESSING APPARATUS AND SUBSTRATE PROCESSING METHOD

(71) Applicant: SEMES CO., LTD., Cheonan-si (KR)

(72) Inventors: Myung Jin LEE, Hwaseong-si (KR); Na Hyun LEE, Ansan-si (KR); Sang Hyeop LEE, Hwaseong-si (KR); Byung Hyuk KANG, Incheon (KR)

(73) Assignee: SEMES CO., LTD., Cheonan-si (KR)

(21) Appl. No.: 19/412,209

(22) Filed: Dec. 8, 2025

(30) Foreign Application Priority Data
Dec. 9, 2024 (KR) 10-2024-0181672

(51) Int. Cl. H10P 72/00; B08B 3/04; B65G 47/90; H10P 72/76

(52) U.S. Cl. CPC H10P 72/0464; B65G 47/90; H10P 72/0458; H10P 72/7602; B08B 3/04

(57) ABSTRACT

The apparatus may include an index module including a plurality of load ports on which a container for accommodating a substrate is placed and a transfer frame in which an index robot for transferring a substrate is installed; a plurality of treating modules each including a plurality of treating chambers vertically stacked in multiple stages and a transfer robot for loading and unloading a substrate to and from the stacked treating chamber; and a plurality of movable buffers configured to temporarily store the substrate, in which the index module and the plurality of treating modules are arranged along a first direction, and each of the plurality of movable buffers is provided to be movable between a standby position accessible by the index robot and a conveyance position accessible by the transfer robot provided to each of the plurality of treating modules.

### CROSS-REFERENCE TO RELATED APPLICATION

This application claims priority to and the benefit of Korean Patent Application No. 10-2024-0181672 filed in the Korean Intellectual Property Office on Dec. 9, 2024, the entire contents of which are incorporated herein by reference.

### TECHNICAL FIELD

The present invention relates to a substrate processing apparatus and a substrate processing method.

### BACKGROUND ART

To manufacture a semiconductor device or liquid crystal display, various processes, such as photolithography, etching, ashing, ion implantation, and thin film deposition, are performed on a substrate. Before or after such a process proceeds, a cleaning process is performed to clean the substrate to remove contaminants and particles generated in each process. In general, the cleaning process includes a process of liquid-treating a substrate.

In order to process a plurality of substrates at the same time, a facility for arranging treating modules in which a plurality of treating chambers is stacked in multiple stages in one direction, and transferring the substrates to respective treating chambers is provided. A transfer robot for transferring the substrate is provided to move horizontally in a direction in which the treating modules are arranged, but when the number of treating modules increases, there is a problem in that the structure of the transfer robot becomes complicated and the process efficiency decreases.

### SUMMARY OF THE INVENTION

The present invention has been made in an effort to provide a substrate processing apparatus capable of efficiently processing a substrate, and a substrate processing method using the same.

The present invention has also been made in an effort to provide a substrate processing apparatus that may simplify a configuration of a treating module, and a substrate processing method using the same.

The present invention has also been made in an effort to provide a substrate processing apparatus that may be easily accessed by a worker and increase the convenience of maintenance, and a substrate processing method using the same.

The objectives of the present disclosure are not limited thereto and other objectives not stated herein may be clearly understood by those skilled in the art from the following description.

An exemplary embodiment of the present disclosure, a substrate processing apparatus comprising: an index module including a plurality of load ports on which a container for accommodating a substrate is placed and a transfer frame in which an index robot for transferring a substrate is installed; a plurality of treating modules each including a plurality of treating chambers vertically stacked in multiple stages and a transfer robot for loading and unloading a substrate to and from the stacked treating chamber; and a plurality of movable buffers configured to temporarily store the substrate, wherein the index module and the plurality of treating modules are arranged along a first direction, and each of the plurality of movable buffers is provided to be movable between a standby position accessible by the index robot and a conveyance position accessible by the transfer robot may provided to each of the plurality of treating modules.

According to the exemplary embodiment of the present invention, wherein each of the plurality of movable buffers may be provided at a different height.

According to the exemplary embodiment of the present invention, wherein each of the plurality of movable buffers may be provided to be horizontally movable along a corresponding traveling shaft among a plurality of traveling shafts installed in parallel with the first direction.

According to the exemplary embodiment of the present invention, wherein the traveling shaft may be disposed between layers of the treating chambers stacked in multiple stages of the treating module.

According to the exemplary embodiment of the present invention, wherein the traveling shaft may be arranged so that the transfer robot does not interfere with a path of loading or unloading the substrate to or from the treating chamber.

According to the exemplary embodiment of the present invention, wherein the plurality of movable buffers includes: a first buffer horizontally movable along a first traveling shaft among the plurality of traveling shafts; and a second buffer horizontally movable along a second traveling shaft among the plurality of traveling shafts, and the plurality of treating modules includes: a first treating module including a first transfer robot; and a second treating module including a second transfer robot, the first buffer is installed to be accessible to the first transfer robot and the second transfer robot, and the second buffer may be installed to be accessible to the first transfer robot and the second transfer robot.

According to the exemplary embodiment of the present invention, wherein the transfer robot may be provided to be movable in a vertical direction along the treating chambers stacked in multiple stages.

According to the exemplary embodiment of the present invention, wherein each of the treating modules includes: a first tower and a second tower including the treating chambers stacked in multiple stages, and a transfer frame in which the transfer robot is installed, and the first tower and the second tower are disposed on opposite sides of the transfer frame, and the first tower, the transfer frame, and the second tower are sequentially may arranged along a second direction.

According to the exemplary embodiment of the present invention, wherein the transfer robot includes: a main body; and an arm mounted on the main body, and the main body may be fixedly installed with respect to the first direction so as not to move along the first direction.

According to the exemplary embodiment of the present invention, wherein the movable buffers may be provided in the same number as the number of treating modules.

According to the exemplary embodiment of the present invention, the apparatus further include a buffer driver for driving the movable buffer, and the buffer driver independently may drives each of the movable buffers.

According to the exemplary embodiment of the present invention, wherein the treating chamber may includes a liquid treating chamber for liquid-treating the substrate.

An exemplary embodiment of the present disclosure, a substrate processing method comprising: providing a plurality of movable buffers which is movable between a standby position for receiving a substrate from an index robot and a conveyance position for providing a substrate to a transfer robot which loads and unloads a substrate to each of treating chambers of a treating module including the treating chambers stacked in multiple stages in a vertical stage, and temporarily stores a substrate, wherein each of the plurality of movable buffers is provided at different heights, each of the plurality of movable buffers is provided to be horizontally movable between the standby position and the conveyance position, a plurality of treating modules may be disposed along a movement direction of the plurality of movable buffers, and each of the plurality of movable buffers receives the substrate from the index robot at the standby position and then moves to the conveyance position so that a transfer robot provided to any one of the plurality of treating modules transfers the substrate.

According to the exemplary embodiment of the present invention, wherein the transfer robot receives the substrate from any one of the plurality of movable buffers and loads the substrate into the treating chamber, and may transfers the substrate that has been completely processed in the treating chamber to one of the plurality of movable buffers.

According to the exemplary embodiment of the present invention, wherein when any one of the plurality of movable buffers transfers the substrate to the transfer robot provided to any one of the plurality of treating modules, a movement schedule of the movable buffer and the transfer robot may be adjusted so that the movable buffer does not collide with the transfer robot provided to the other of the treating modules on a transfer path.

An exemplary embodiment of the present disclosure, a substrate processing apparatus comprising: an index module including a plurality of load ports on which a container for accommodating a substrate is placed and a transfer frame in which an index robot for transferring a substrate is installed; a plurality of treating modules each including a plurality of treating chambers vertically stacked in multiple stages and a transfer robot for loading and unloading a substrate to and from the stacked treating chamber; and a plurality of movable buffers configured to temporarily store the substrate, wherein the index module and the plurality of treating modules are arranged along a first direction, and each of the treating modules includes: a first tower and a second tower including the treating chambers stacked in multiple stages, and a transfer frame in which the transfer robot and the movable buffer are installed, the first tower and the second tower are disposed on opposite sides of the transfer frame, the first tower, the transfer frame, and the second tower are sequentially arranged along a second direction, each of the plurality of movable buffers is provided at different heights, each of the plurality of movable buffers is provided to be horizontally movable along a corresponding traveling shaft among a plurality of traveling shafts installed in parallel with the first direction in the transfer frame, and the transfer robot may be provided to be movable in a vertical direction along the treating chambers stacked in multiple stages.

According to the exemplary embodiment of the present invention, wherein each of the plurality of movable buffers is provided to be movable between a standby position accessible by the index robot and a conveyance position accessible by the transfer robot may provided to each of the plurality of treating modules.

According to the exemplary embodiment of the present invention, wherein the traveling shaft is disposed between layers of the treating chambers stacked in multiple stages of the treating module, and the traveling shaft may be arranged so that the transfer robot does not interfere with a path of loading or unloading the substrate to or from the treating chamber.

According to the exemplary embodiment of the present invention, wherein the plurality of movable buffers includes: a first buffer horizontally movable along a first traveling shaft among the plurality of traveling shafts; and a second buffer horizontally movable along a second traveling shaft among the plurality of traveling shafts, and the plurality of treating modules includes: a first treating module including a first transfer robot; and a second treating module including a second transfer robot, the first buffer is installed to be accessible to the first transfer robot and the second transfer robot, and the second buffer may be installed to be accessible to the first transfer robot and the second transfer robot.

According to the exemplary embodiment of the present invention, wherein the transfer robot includes: a main body; and an arm mounted on the main body, and the main body may be fixedly installed with respect to the first direction so as not to move along the first direction.

According to the exemplary embodiment of the present invention, it is possible to efficiently process a substrate.

Further, according to the exemplary embodiment of the present invention, it is possible to simplify a configuration of a treating module.

Further, according to the exemplary embodiment of the present invention, it is possible to provide a facility that may be easily accessed by a worker, and to increase the convenience of maintenance of the facility.

Effects of the present disclosure are not limited to those described above and effects not stated above will be clearly understood to those skilled in the art from the specification and the accompanying drawings.

### BRIEF DESCRIPTION OF THE DRAWINGS

The various features and advantages of the non-limiting exemplary embodiment of the present specification may become more apparent by reviewing the detailed description together with the accompanying drawings. The accompanying drawings are provided for illustrative purposes only and should not be construed as limiting the scope of claims. The accompanying drawings are not considered to be drawn to scale unless explicitly stated. For clarity, the various dimensions of the drawings may have been exaggerated.

FIG. 1 is a top plan view schematically illustrating a substrate processing apparatus according to an exemplary embodiment of the present invention.

FIG. 2 is a diagram schematically illustrating the substrate processing apparatus of FIG. 1 when viewed from the side.

FIG. 3 is a perspective view illustrating an exemplary embodiment of a transfer robot of the present invention.

FIG. 4 is a flowchart of a substrate processing method of the present invention.

FIGS. 5 to 8 are diagrams illustrating operations of the substrate processing apparatus of FIG. 1 according to the flowchart of FIG. 4.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, the present invention will be described based on the case where a substrate processing process is a process of liquid treating a substrate W by supplying a liquid, such as a cleaning liquid, onto the substrate W as an example. However, the present exemplary embodiment is not limited to the cleaning process, and may be applied to various processes for processing the substrate W using a liquid, such as an etching process, an ashing process, or a developing process.

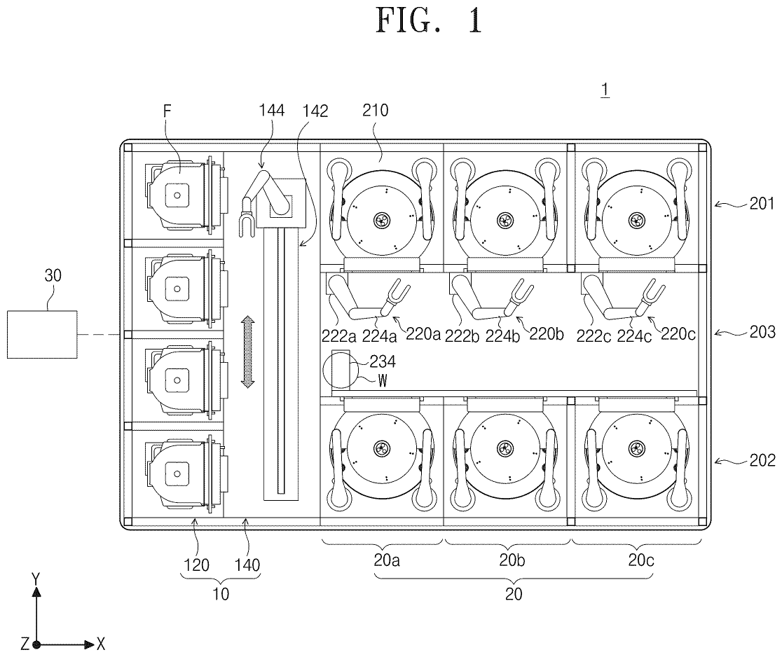

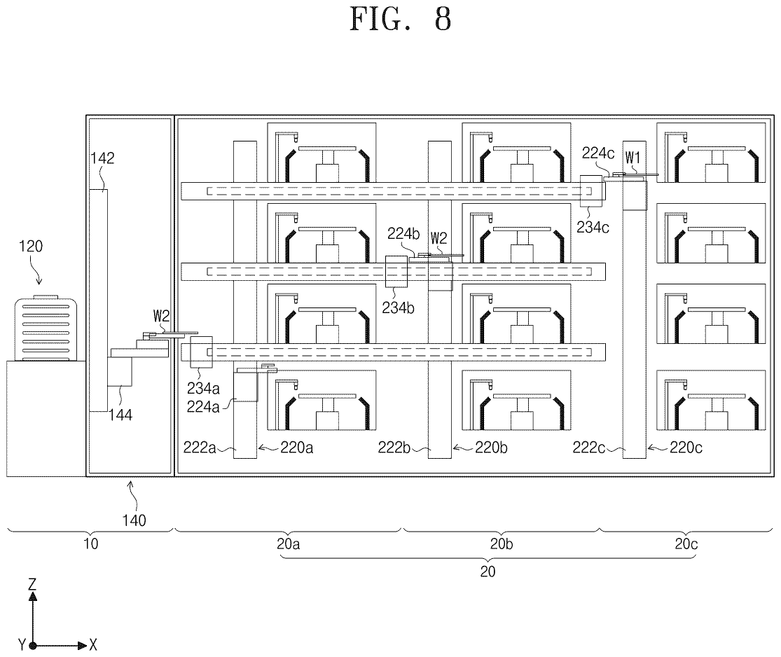

Hereinafter, an exemplary embodiment of the present invention will be described in detail with reference to FIGS. 1 to 8. A substrate processing apparatus 1 according to an exemplary embodiment of the present invention may perform a cleaning process including a drying process of drying a substrate W using a process fluid.

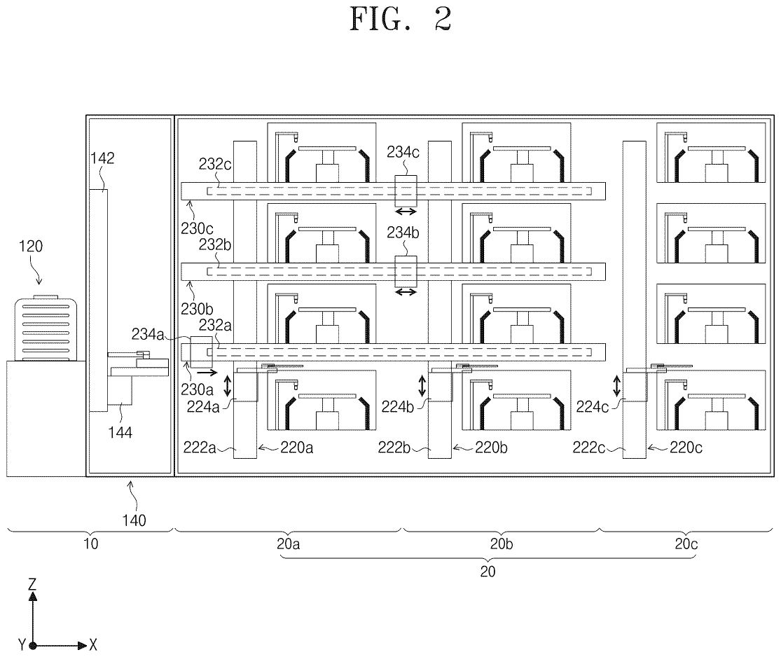

FIG. 1 is a top plan view schematically illustrating a substrate processing apparatus according to an exemplary embodiment of the present invention, and FIG. 2 is a diagram schematically illustrating the substrate processing apparatus of FIG. 1 when viewed from the side.

Referring to FIGS. 1 and 2, a substrate processing apparatus 1 includes an index module 10, a treating module 20, a buffer module 230, and a controller 30. According to an example, the index module 10 and the treating module 20 are disposed along one direction. A plurality of treating modules 20 may be provided. The buffer module 230 may be installed in the treating module 20.

Hereinafter, a direction in which the index module 10 and the treating module 20 are arranged side by side is defined as a first direction X. When viewed from the top, a direction perpendicular to the first direction X is defined as a second direction Y, and a direction perpendicular to a plane including both the first direction X and the second direction Y is defined as a third direction Z.

The index module 10 transfers a substrate W from a container F in which the substrate W is accommodated to the treating module 20 treating the substrate W. The index module 10 accommodates the substrate W completely processed in the treating module 20 into the container F. A longitudinal direction of the index module 10 is provided in the second direction Y. The index module 10 includes a load port 120 and an index frame 140.

The container F in which the substrate W is accommodated is seated on the load port 120. Based on the index frame 140, the load port 120 is located at a side opposite to the treating module 20. A plurality of load ports 120 may be provided. The plurality of load ports 120 may be arranged in a line along the second direction Y. The number of load ports 120 may increase or decrease according to the process efficiency and footprint conditions of the treating module 20.

A plurality of slots (not illustrated) is formed in the container F. The slots (not illustrated) may accommodate the substrates W in a state in which the substrates W are disposed horizontally with respect to the ground. As the container F, an airtight container, such as a Front Open Unified Pod (FOUP), may be used. The container F may be placed on the load port 120 by a transfer means (not illustrated), such as an overhead transfer, an overhead conveyor, or an automatic guided vehicle, or an operator.

An index rail 142 and an index robot 144 are provided inside the index frame 140. The index rail 142 is provided in the index frame 140 along the second direction Y in its longitudinal direction. The index robot 144 may transfer the substrate W. The index robot 144 may transfer the substrate W between the index module 10 and the treating module 20 to be described later. The index robot 144 may transfer the substrate W between the load port 120 and a buffer 234 to be described later.

The index robot 144 includes an index hand (not illustrated). The substrate W is seated on the index hand (not illustrated). The index hand (not illustrated) may be provided on the index rail 142 to be movable along the second direction Y. Accordingly, the transfer hand (not illustrated) may be moved forward and backward along the guide rail 142. Also, the index hand (not illustrated) may be provided to be rotatable with respect to the third direction Z. Also, the index robot 144 may be provided to be vertically movable along the third direction Z. A plurality of index hands (not illustrated) may be provided. A plurality of index hands (not illustrated) may be provided to be spaced apart from each other in the vertical direction. A plurality of index hands 146 may move forward, backward, and rotate independently of each other.

The controller 30 controls the substrate processing apparatus 1. The controller 30 may include a process controller formed of a microprocessor (computer) that executes the control of the substrate processing apparatus 1, a user interface formed of a keyboard in which an operator performs a command input operation or the like in order to manage the substrate processing apparatus 1, a display for visualizing and displaying an operation situation of the substrate processing apparatus 1, and the like, and a storage unit storing a control program for executing the process executed in the substrate processing apparatus 1 under the control of the process controller or a program, that is, a treating recipe, for executing the process in each component according to various data and treating conditions. Further, the user interface and the storage unit may be connected to the process controller. The processing recipe may be stored in a storage medium in the storage unit, and the storage medium may be a hard disk, and may also be a portable disk, such as a CD-ROM or a DVD, or a semiconductor memory, such as a flash memory.

The controller 30 may control the substrate processing apparatus 1 to perform the substrate processing method described below. For example, the controller 30 may control the configurations provided to the transfer robot 300 and the treating chamber 210 so as to perform a substrate processing method described below.

The treating module 20 includes a first tower 201, a second tower 202, and a transfer frame 203. Each of the first tower 201 and the second tower 202 includes treating chambers 210 stacked in multiple stages.

The transfer frame 203 provides a transfer space for transferring the substrate W between the index robot 144 and the treating chamber 210, or between the treating chambers 210.

A longitudinal direction of the transfer frame 203 may be provided along the first direction X. The first tower 201 and the second tower 202 may be disposed on both sides of the transfer frame 203, respectively. The treating chamber 210 of the transfer frame 203 may be disposed. The treating chamber 210 may be disposed on the side of the transfer frame 203. The first tower 201, the transfer frame 203, and the second tower 202 may be sequentially arranged along the second direction Y.

According to an example, each of the first tower 201 and the second tower 202 may include the treating chambers 210 stacked in multiple stages. The treating chambers 210 may be stacked in multiple stages along the third direction Z. In the following exemplary embodiment, the present invention will be described based on the case where each of the first tower 201 and the second tower 202 are provided to include the treating chambers 210 stacked in four stages, but the number of treating chambers 210 stacked in multiple stages in the first tower 201 and the second tower 202 may increase or decrease, and the number of treating chambers 210 stacked in the first tower 201 and the number of treating chambers 210 stacked in the second tower 202 may be provided differently from each other.

The transfer frame 203 includes a guide rail 222 and a transfer robot 224. The guide rail 222 and the transfer robot 224 together may be referred to as a transfer module 220. The guide rail 222 is provided within the transfer frame 203 with its longitudinal direction in the third direction Z. The guide rail 222 may be provided adjacent to any one of the first tower 201 and the second tower 202 of the corresponding treating module 20. For example, as illustrated in FIG. 1, the guide rails 222 may be provided to be closer to the first tower 201 between the first tower 201 and the second tower 202. When viewed from the second direction Y, the guide rails 222 may be arranged not to overlap an entrance port through which the substrate W enters and exist from the treating chamber 210.

The transfer robot 224 may be provided on the guide rail 222 to be linearly movable along the third direction Z. The transfer robot 224 may be provided to be movable in a vertical direction along the treating chambers 210 stacked in multiple stages on the guide rail 222. The transfer robot 224 may transfer the substrate W between the buffer 234 and the treating chamber 210 to be described later.

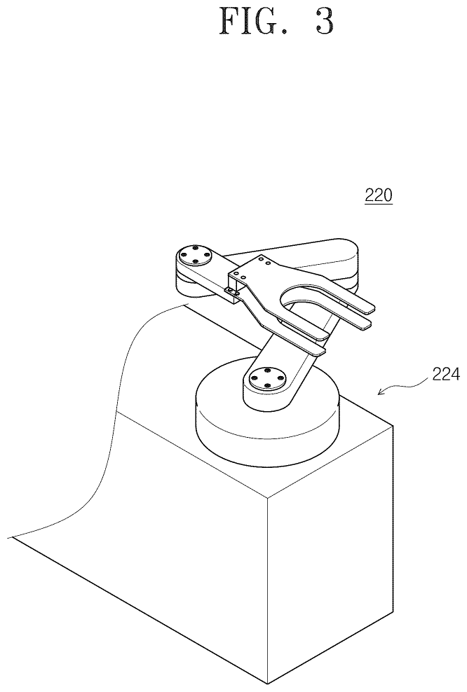

FIG. 3 is a perspective view illustrating an exemplary embodiment of the transfer robot of the present invention. Referring to FIG. 3, the transfer robot 224 may be, for example, a Selective Compliance Assembly Robot Arm (SCARA) having a multi-joint form. The transfer robot 224 may be fixedly installed on the guide rail 222 provided along the third direction Z. The transfer robot 224 may include a main body (not illustrated) and an articulated arm (not illustrated) connected to the main body. The main body (not illustrated) may be fixedly installed on the guide rail 222 and restricted from moving in the first direction X or the second direction Y, and may be provided to be movable along the third direction Z.

The articulated arm (not illustrated) may be provided with a swiveling motion of unfolding or folding by a driving means installed in the main body (not illustrated). The articulated arm (not illustrated) may perform lifting and rotating motion. The form and structure of the articulated arm (not illustrated) may be configured by variously modifying the shape, quantity, and the like of the link in consideration of the structure of the manufacturing process, the transfer distance of the substrate, and the like.

Referring back to FIGS. 1 and 2, the treating chamber 210 may process the substrate W. The treating chamber 210 may be a chamber configured to perform a cleaning process for removing process by-products or the like adhering to the substrate W. The treating chamber 210 may be provided as, for example, a liquid treating chamber to perform a liquid treatment process for liquid-treating the substrate W by supplying a liquid onto the substrate W. Hereinafter, the present invention will be described based on the case where the treating chamber 210 is a liquid treating chamber. The liquid treating chamber may process the substrate W by supplying a chemical, a rinse liquid, and/or an organic solvent onto the substrate W. The processing of the substrate W performed in the liquid treating chamber may include a spin drying treatment of removing the liquid remaining on the substrate W by rotating the substrate W.

The treating chambers 210 may have different structures depending on the type of a process for treating the substrate W. Alternatively, each of the treating chambers 210 may have the same structure. Hereinafter, for convenience of description, it will be described that each of the treating chambers 210 has the same structure.

A plurality of treating modules 20 may be provided. A plurality of treating modules 20 may be arranged in parallel along the first direction X. For example, as illustrated in FIGS. 1 and 2, the treating module 20 may include a first treating module 20a, a second treating module 20b, and a third treating module 20c, and the index module 10, the first treating module 20a, the second treating module 20b, and the third treating module 20c may be arranged in parallel along the first direction X. In the following exemplary embodiment, for convenience of description, it will be illustrated and described that three treating modules 20a, 20b, and 20c are provided, but the number of treating modules 20 is not limited, and two or more treating modules 20 may be provided.

As described above, each treating module 20 includes the first tower 201 and the second tower 202 in which the plurality of treating chambers 210 is stacked in multiple stages, and includes the transfer module 220 provided in the transfer frame 203 between the first tower 201 and the second tower 202.

For example, the first treating module 20a includes a first tower 201a and a second tower 202a in which a plurality of treating chambers 210a is arranged in multiple stages, and includes a first transfer module 220a provided on the transfer frame 203 between the first tower 201a and the second tower 202a. The first transfer module 220a includes a first guide rail 222a and a first transfer robot 224a.

The second treating module 20b includes a first tower 201b and a second tower 202b in which a plurality of treating chambers 210b is disposed in multiple stages, and includes a second transfer module 220b provided on the transfer frame 203 between the first tower 201b and the second tower 202b. The second transfer module 220b includes a second guide rail 222b and a second transfer robot 224b.

The third treating module 20c includes a first tower 201c and a second tower 202c each having a plurality of treating chambers 210c arranged in multiple stages, and includes a third transfer module 220c provided on the transfer frame 203 between the first tower 201c and the second tower 202c. The third transfer module 220c includes a third guide rail 222c and a third transfer robot 224c.

The buffer module 230 may transfer the substrate W between the transfer robot 224 installed in the transfer frame 203 and the index module 10. The buffer module 230 may be installed in the transfer frame 203. The buffer module 230 includes a traveling shaft 232, the buffer 234, and a buffer driver (not illustrated).

The traveling shaft 232 is provided within the transfer frame 203 with its longitudinal direction in parallel with the first direction X. The traveling shaft 232 may be provided along the plurality of treating modules 20a, 20b, and 20c such that the buffer 234 moving along the traveling shaft 232 may access the transfer robots 224a, 224b, and 224c provided to the plurality of treating modules 20a, 20b, and 20c, respectively. The traveling shaft 232 may be provided adjacent to any one of the first tower 201 and the second tower 202 of the treating module 20. A tower adjacent to the traveling shaft 232 may be a tower different from a tower adjacent to the guide rail 222. For example, as illustrated in FIG. 1, the guide rail 222 of the transfer module 220 may be provided closer to the first tower 201 of the first tower 201 and the second tower 202, and the traveling shaft 232 may be provided closer to the second tower 202 between the first tower 201 and the second tower 202.

The driving shaft 232 may be arranged so as not to interfere with a path through which the transfer robot 224 loads the substrate W into the treating chamber 210 and a path through which the substrate W is unloaded from the treating chamber 210. For example, as illustrated in FIG. 2, the driving shaft 232 may be placed between layers of the treating chambers 210 stacked in multiple stages of the treating module 20.

The buffer 234 may be disposed on the traveling shaft 232 to be horizontally movable along the corresponding traveling shaft 232. The buffer 234 may be provided as a movement buffer horizontally movable along the traveling shaft 232. Hereinafter, it will be described on the premise that the buffer 234 is a movement buffer that moves along the traveling shaft 232. The buffer 234 may transfer the substrate W to the index robot 144 and the transfer robot 224.

A slot (not illustrated) in which the substrate W is placed is provided in the buffer 234. A plurality of slots (not illustrated) is provided. A plurality of slots (not illustrated) may be disposed to be spaced apart from each other along the third direction Z. A front face and a rear face of the buffer 234 are opened. The front face may be the surface facing the index module 10 along the first direction X, and the rear face may be the surface away from the index module 10 along the first direction X. The index robot 144 may access the buffer 234 through the front face to load the substrate W into the buffer 234 or unload the substrate W from the buffer 234, and the transfer robot 224 may access the buffer 234 through the rear face to load in the substrate W into the buffer 234 or unload the substrate W from the buffer 234.

The buffer 234 may move along the traveling shaft 232 between a standby position to which the index robot is accessible 144 and a conveyance position to which the transfer robot 224 is accessible. The buffer 234 may move to the standby position to receive the substrate W from the index robot 144, and then may transfer the substrate W to any one transfer robot 224 of the transfer robots 224a, 224b, and 224c provided to the plurality of treating modules 20a, 20b, and 20c, respectively. For example, the buffer 234 may move to a first robot conveyance position accessible by the first transfer robot 224a, a second robot conveyance position accessible by the second transfer robot 224b, and a third robot conveyance position accessible by the third transfer robot 224c on the traveling shaft 232, and transfer the substrate W to the transfer robot 224a, which is accessible to the corresponding conveyance position.

The buffer 234 may move to the conveyance position to receive the substrate W from any one transfer robot 224 of the transfer robots 224a, 224b, and 224c provided to the plurality of treating modules 20a, 20b, and 20c, respectively, and then move to the standby position to transfer the substrate W to the index robot 144.

For example, the buffer 234 may move to any one of the first robot conveyance position, the second robot conveyance position, and the third robot conveyance position on the driving shaft 232 to receive the substrate W from the transfer robot 224 that is accessible to the corresponding conveyance position, and then move to the standby position to transfer the substrate W to the index robot 144.

The buffer driver (not illustrated) may drive the buffer 234 so that the buffer 234 moves horizontally along the traveling shaft 232.

A plurality of buffer modules 230 may be provided. A plurality of buffer modules 230 may be installed in the transfer frame 203. Each of the buffer modules 230 may be provided at different heights within the transfer frame 203.

The number of buffer modules 230 may be equal to the number of treating modules 20. For example, as illustrated in FIGS. 1 and 2, hereinafter, it will be illustrated and described as three buffer modules 230 including the first buffer module 230a, the second buffer module 230b, and the third buffer module 230c are provided. However, unlike the following exemplary embodiment, the number of buffer modules 230 may be provided differently from the number of treating modules 20.

The first buffer module 230a includes a first traveling shaft 232a, a first buffer 234a, and a first buffer driver (not illustrated), the second buffer module 230b includes a second traveling shaft 232b, a second buffer 234b, a second buffer driver (not illustrated), and the third buffer module 230c includes a third traveling shaft 232c, a third buffer 234c, and a third buffer driver (not illustrated).

The first buffer module 230a, the second buffer module 230b, and the third buffer module 230c may be provided at different heights, respectively. For example, the first traveling shaft 232a may be disposed between the first layer and the second layer of the treating chambers 210 stacked in multiple stages of the treating module 20, the second traveling shaft 232b may be disposed between the second layer and the third layer of the treating chambers 210 stacked in multiple stages of the treating module 20, and the third traveling shaft 232c may be disposed between the third layer and the fourth layer of the treating chambers 210 stacked in multiple stages of the treating module 20.

Each of the buffers 234a, 234b, and 234c may horizontally move along the corresponding traveling shaft 232a, 232b, and 232c. Each of the buffers 234a, 234b, and 234c may horizontally move along the corresponding traveling shaft 232a, 232b, and 232c to transfer the substrate W to any one transfer robot 224 of the transfer robots 224a, 224b, and 224c provided to the plurality of treating modules 20a, 20c, respectively.

Each of the buffers 234a, 234b, and 234c may move to the conveyance position to receive the substrate W from any one transfer robot 224 of the transfer robots 224a, 224b, and 224c provided to the plurality of treating modules 20a, 20b, and 20c, respectively, and then move to the standby position to transfer the substrate W to the index robot 144.

The buffer drivers provided to each of the buffer modules 230a, 230b, and 230c, respectively, may independently drive corresponding buffers.

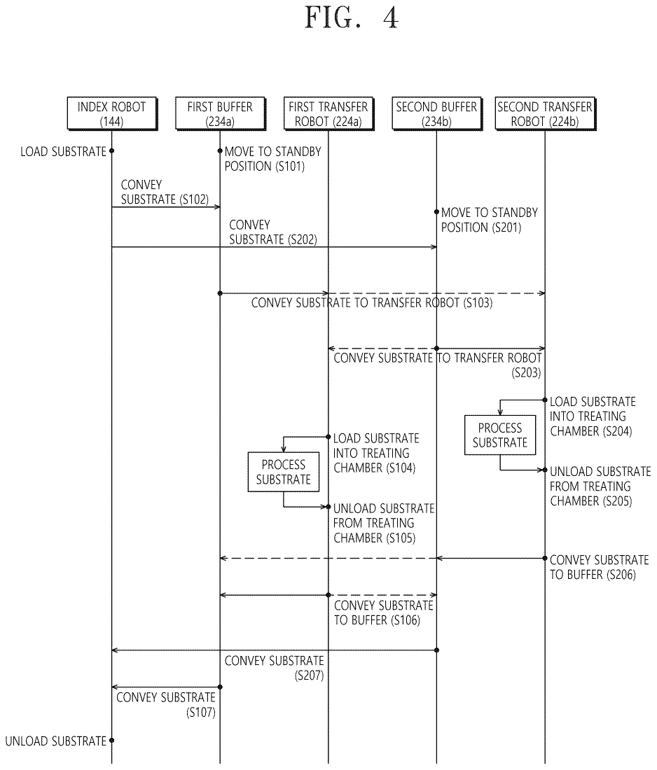

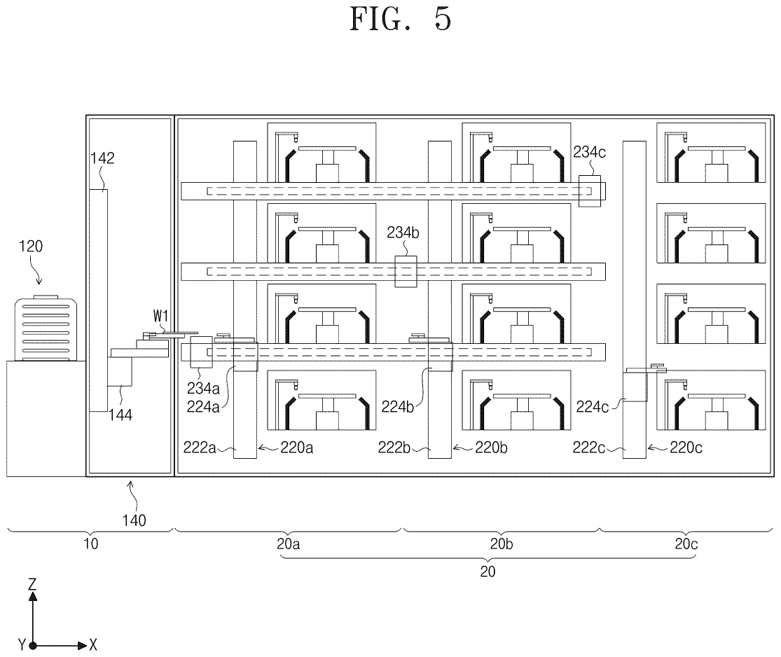

FIG. 4 is a flowchart of a substrate processing method of the present invention, and FIGS. 5 to 8 are diagrams illustrating operations of the substrate processing apparatus of FIG. 1 according to the flowchart of FIG. 4.

Hereinafter, an exemplary embodiment of a method of processing a substrate by using the substrate processing apparatus of FIG. 1 will be described with reference to FIGS. 4 to 8. The substrate processing method described below may be performed by the substrate processing apparatus 1 including the index module 10, the treating module 20, and the buffer module 230. Further, the controller 30 may perform the substrate processing method described below by controlling the configurations of the substrate processing apparatus 1, such as the index module 10, the treating module 20, the buffer module 230, and the like.

In FIG. 5 to FIG. 8, for convenience of description, the substrate W1 before treatment, which is not treated in the treating chamber 210, and the substrate W2 after treatment, which has been treated in the treating chamber 210, are to be illustrated separately. Also, for convenience of description, configurations of the third treating module 20c and the third buffer module 230c are illustrated in FIG. 5 to FIG. 8, but illustrations thereof are to be omitted in FIG. 4.

Referring to FIG. 4, the substrate processing method according to the exemplary embodiment of the present invention may be explained by the interaction between the index robot 144, the first buffer 234a, the first transfer robot 224a, the second buffer 234b, and the second transfer robot 224b.

The substrate W1 before processing is loaded into the index module 10 from the outside and conveyed to the first buffer 234a by the index robot 144. As illustrated in FIG. 5, the first buffer 234a moves along the first traveling shaft 232a to the standby position accessible by the index robot 144 S101, and the index robot 144 may unload the substrate W1 before processing accommodated in the container F of the load port 120 and transfer the substrate W1 to the first buffer 234a (S102).

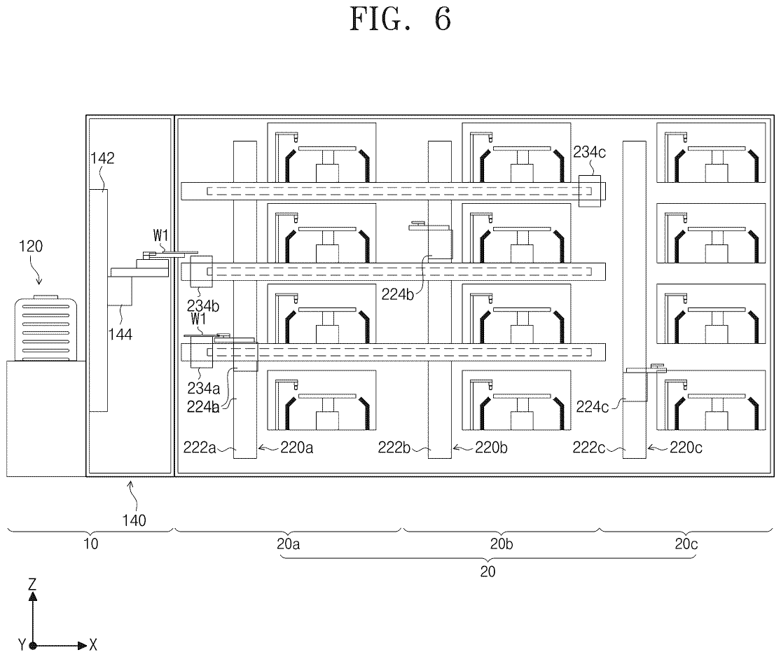

As illustrated in FIG. 6, the first buffer 234a transfers the substrate W1 before processing received from the index robot 144 to any one transfer robot 224 of the transfer robots 224a, 224b, and 224c provided to the plurality of treating modules 20a, 20b, and 20c, respectively, for example, the first transfer robot 224a (S103).

The first transfer robot 224a loads the substrate W1 before processing received to any one of the plurality of treating chambers 210 stacked in multiple stages of the first treating module 20a (S104), and the substrate W is processed in the corresponding treating chamber 210.

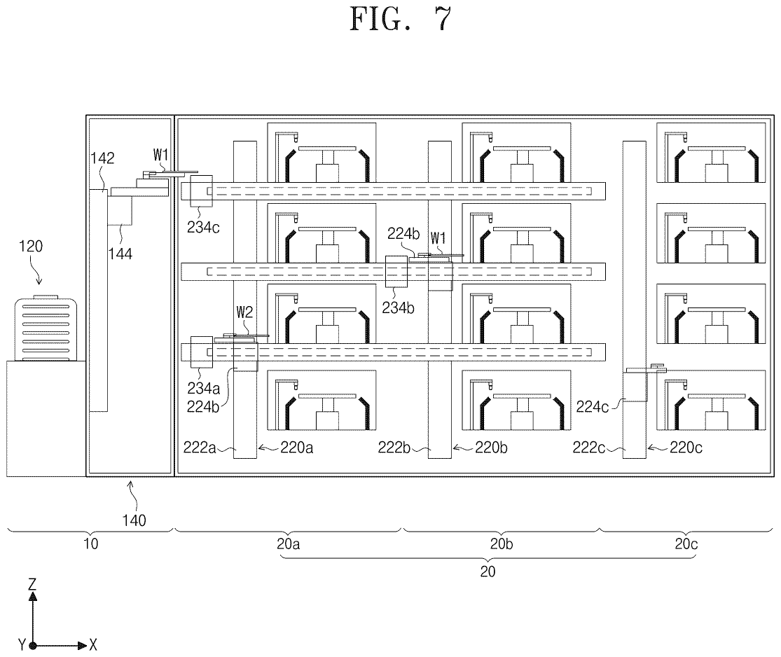

As illustrated in FIG. 7, the first transfer robot 224a unloads the substrate W2 after processing from the treating chamber 210, and conveys the substrate W2 to the buffer 234 (S106). In this case, the first transfer robot 224a may convey the substrate W2 after processing to any one buffer 234 of the plurality of buffers 234a, 234b, and 234c, for example, the first buffer 234a.

The first buffer 234a conveys the received substrate W2 after processing to the index robot 144 (S107), and the index robot 144 may load and accommodated the substrate W2 after processing in the container F of the load port 120.

In the same manner as in the above-described exemplary embodiment, each of the plurality of buffers 234a, 234b, and 234c may convey the substrate W1 before processing received from the index robot 144 to any one transfer robot 224 of the transfer robots 224a, 224b, and 224c provided to the plurality of treating modules 20a, 20b, and 20c, respectively, and further, may receive the substrate W2 after processing from any one transfer robot 224 of the transfer robots 224a, 224b, and 224c and convey the substrate W2 after processing to the index robot 144. Although the description is omitted in the above-described exemplary embodiment, a substrate processing method related to the second buffer 234b and the second transfer robot 224b is illustrated and described in FIGS. 4 and 5 to 8.

In the above-described substrate processing method, the controller 30 may control the plurality of buffers 234a, 234b, and 234c to approach the corresponding transfer robot 224 according to the schedule of loading the substrate W1 before processing into the treating chamber 210 by the transfer robots 224a, 224b, and 224c or unloading the substrate W2 after processing from the treating chamber 210, in consideration of a schedule for processing the substrate W in each of the treating chambers 210 provided to the plurality of treating modules 20a, 20b, and 20c, respectively.

In the substrate processing method described above, the controller 30 may adjust and control the movement schedule of the buffer 234 and the transfer robot 224 so that no collision occurs between the buffer 234 and the transfer robots 224 provided to other treating modules 20 when the plurality of the buffers 234a, 234b, and 234c transfer the substrate W to the transfer robots 224a, 224c. In this case, an interlock for preventing a collision between the buffer 234 and the transfer robot 224 may be provided.

According to the above-described exemplary embodiment, in the substrate processing apparatus 1 according to the exemplary embodiment of the present invention, the plurality of treating modules 20 is arranged side by side along the first direction X, each treating module 20 is provided with the transfer robot 224 movable along the third direction Z, and the plurality of buffers 234 is provided to transfer the substrate W to the plurality of transfer robots 224. Accordingly, the facility configuration may be simplified by modularizing the configuration of the treating module 20.

In the substrate processing apparatus 1 according to the exemplary embodiment of the present invention, since the plurality of buffers 234 may exchange the substrate W with all the transfer robots 224, the substrate W transfer efficiency of the substrate processing apparatus 1 including the plurality of treating modules 20 may increase and the production amount of the treating chamber 210 may be maximized.

In the substrate processing apparatus 1 according to the exemplary embodiment of the present invention, as the transfer module 220 is configured so that the transfer robot 224 moves only in the third direction Z without moving along the first direction X, which is the direction in which the treating module 20 is disposed, the operator may easily access the transfer frame 203, and the convenience of maintenance of the transfer frame 203 and the treating module 20 may be improved.

In the above-described exemplary embodiment, the plurality of buffers 234a, 234b, and 234c is illustrated and described as conveying the substrate W or receiving the substrate W to or from any one transfer robot 224 of the transfer robots 224a, 224b, and 224c provided to the plurality of treating modules 20a, 20b, and 20c, respectively. However, unlike this, each of the plurality of buffers 234a, 234b, and 234c may correspond to a single transfer robot 224 and may be provided to convey the substrate W only to the corresponding transfer robot 224.

In the above-described exemplary embodiment, it has been illustrated and described that all of the plurality of buffers 234a, 234b, and 234c are movable buffers. However, unlike this, one or more buffers 234 among the buffers 234a, 234b, and 234c may be fixedly installed and provided. For example, the buffer 234 may be fixedly installed at a position where both the index robot 144 and the first transport robot 224a may be accessible.

In the above-described exemplary embodiment, the present invention has been described based on the case where the treating chamber 210 is a liquid treating chamber for liquid-treating the substrate W as an example. However, unlike this, the treating chamber 210 may be a drying chamber for dry-treating the substrate W, or may further include a drying chamber in addition to the liquid treating chamber. The drying chamber may be a supercritical chamber for drying a substrate using a supercritical fluid.

In the above exemplary embodiment, it has been illustrated and described that the transfer robot 224 is a SCARA robot having an articulated arm. However, unlike this, the transfer robot 224 may be provided as a robot having an orthogonal hand that moves forward and backward with respect to the main body, and the main body of the robot may be provided to rotate in the third direction Z with respect to the guide rail 222.

The specification described above provides examples of the present disclosure. Further, the description provides exemplary embodiments of the present disclosure and the present disclosure may be used in other various combinations, changes, and environments. That is, the present disclosure may be changed or modified within the scope of the present disclosure described herein, within a range equivalent to the description, and/or within the knowledge or technology in the related art. The embodiment shows an optimum state for achieving the spirit of the present disclosure and may be changed in various ways for the detailed application fields and use of the present disclosure. Therefore, the detailed description of the present disclosure is not intended to limit the present disclosure in the embodiment. Further, the claims should be construed as including other embodiments.

1. A substrate processing apparatus comprising:
an index module including a plurality of load ports on which a container for accommodating a substrate is placed and a transfer frame in which an index robot for transferring a substrate is installed;
a plurality of treating modules each including a plurality of treating chambers vertically stacked in multiple stages and a transfer robot for loading and unloading a substrate to and from the stacked treating chamber; and
a plurality of movable buffers configured to temporarily store the substrate,
wherein the index module and the plurality of treating modules are arranged along a first direction, and
each of the plurality of movable buffers is provided to be movable between a standby position accessible by the index robot and a conveyance position accessible by the transfer robot provided to each of the plurality of treating modules.

2. The substrate processing apparatus of claim 1, wherein each of the plurality of movable buffers is provided at a different height.

3. The substrate processing apparatus of claim 2, wherein each of the plurality of movable buffers is provided to be horizontally movable along a corresponding traveling shaft among a plurality of traveling shafts installed in parallel with the first direction.

4. The substrate processing apparatus of claim 3, wherein the traveling shaft is disposed between layers of the treating chambers stacked in multiple stages of the treating module.

5. The substrate processing apparatus of claim 3, wherein the traveling shaft is arranged so that the transfer robot does not interfere with a path of loading or unloading the substrate to or from the treating chamber.

6. The substrate processing apparatus of claim 3, wherein the plurality of movable buffers includes:
a first buffer horizontally movable along a first traveling shaft among the plurality of traveling shafts; and
a second buffer horizontally movable along a second traveling shaft among the plurality of traveling shafts, and
the plurality of treating modules includes:
a first treating module including a first transfer robot; and
a second treating module including a second transfer robot,
the first buffer is installed to be accessible to the first transfer robot and the second transfer robot, and
the second buffer is installed to be accessible to the first transfer robot and the second transfer robot.

7. The substrate processing apparatus of claim 1, wherein the transfer robot is provided to be movable in a vertical direction along the treating chambers stacked in multiple stages.

8. The substrate processing apparatus of claim 1, wherein each of the treating modules includes:
a first tower and a second tower including the treating chambers stacked in multiple stages, and
a transfer frame in which the transfer robot is installed, and
the first tower and the second tower are disposed on opposite sides of the transfer frame, and
the first tower, the transfer frame, and the second tower are sequentially arranged along a second direction.

9. The substrate processing apparatus of claim 8, wherein the transfer robot includes:
a main body; and
an arm mounted on the main body, and
the main body is fixedly installed with respect to the first direction so as not to move along the first direction.

10. The substrate processing apparatus of claim 1, wherein the movable buffers are provided in the same number as the number of treating modules.

11. The substrate processing apparatus of claim 1, further comprising:
a buffer driver for driving the movable buffer, and
the buffer driver independently drives each of the movable buffers.

12. The substrate processing apparatus of claim 1, wherein the treating chamber includes a liquid treating chamber for liquid-treating the substrate.

13-15. (canceled)

16. A substrate processing apparatus comprising:
an index module including a plurality of load ports on which a container for accommodating a substrate is placed and a transfer frame in which an index robot for transferring a substrate is installed;
a plurality of treating modules each including a plurality of treating chambers vertically stacked in multiple stages and a transfer robot for loading and unloading a substrate to and from the stacked treating chamber; and
a plurality of movable buffers configured to temporarily store the substrate,
wherein the index module and the plurality of treating modules are arranged along a first direction, and
each of the treating modules includes:
a first tower and a second tower including the treating chambers stacked in multiple stages, and
a transfer frame in which the transfer robot and the movable buffer are installed,
the first tower and the second tower are disposed on opposite sides of the transfer frame,
the first tower, the transfer frame, and the second tower are sequentially arranged along a second direction,
each of the plurality of movable buffers is provided at different heights,
each of the plurality of movable buffers is provided to be horizontally movable along a corresponding traveling shaft among a plurality of traveling shafts installed in parallel with the first direction in the transfer frame, and
the transfer robot is provided to be movable in a vertical direction along the treating chambers stacked in multiple stages.

17. The substrate processing apparatus of claim 16, wherein each of the plurality of movable buffers is provided to be movable between a standby position accessible by the index robot and a conveyance position accessible by the transfer robot provided to each of the plurality of treating modules.

18. The substrate processing apparatus of claim 16, wherein the traveling shaft is disposed between layers of the treating chambers stacked in multiple stages of the treating module, and
the traveling shaft is arranged so that the transfer robot does not interfere with a path of loading or unloading the substrate to or from the treating chamber.

19. The substrate processing apparatus of claim 16, wherein the plurality of movable buffers includes:
a first buffer horizontally movable along a first traveling shaft among the plurality of traveling shafts; and
a second buffer horizontally movable along a second traveling shaft among the plurality of traveling shafts, and
the plurality of treating modules includes:
a first treating module including a first transfer robot; and
a second treating module including a second transfer robot,
the first buffer is installed to be accessible to the first transfer robot and the second transfer robot, and
the second buffer is installed to be accessible to the first transfer robot and the second transfer robot.

20. The substrate processing apparatus of claim 16, wherein the transfer robot includes:
a main body; and
an arm mounted on the main body, and
the main body is fixedly installed with respect to the first direction so as not to move along the first direction.
